(19) United States
(12) Patent Application Publication
(10) Pub. No.: US 2008/0174027 A1
(43) Pub. Date: Jul. 24, 2008

(54) SEMICONDUCTOR INTERCONNECT STRUCTURE WITH ROUNDED EDGES AND METHOD FOR FORMING THE SAME

(75) Inventors: Chien-Chang Fang, Fongshan City (TW); Li Te Hsu, Tainan County (TW); Chia-Chi Chung, Hsinchu (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/625,527

(22) Filed: Jan. 22, 2007

(51) Int. Cl. H01L 23/48; H01L 21/00

(52) U.S. Cl. 257/774; 438/618; 257/E23.01; 257/E21.001

(57) ABSTRACT

Provided is a semiconductor interconnect structure formed from an original damascene or dual damascene structure. The original damascene or dual damascene structure includes a planar upper surface consisting of planar upper surfaces of conductive structures formed within openings formed in the dielectric, and planar upper surfaces of the dielectric. The original structure is processed using wet or dry etching operations which, by including ion bombardment and/or ion milling characteristics, both etch the upper dielectric surface and round the upper edges of the originally formed interconnect structures that become exposed as the dielectric is etched. Produced is an interconnect structure within an opening formed in a dielectric and which includes an upper portion that extends above the dielectric and includes opposed upper edges that are rounded.

### FIELD OF THE INVENTION

The present invention relates, most generally, to semiconductor device manufacturing and, more particularly, to methods for forming leakage resistant interconnect devices.

### BACKGROUND

Interconnect structures are commonly formed in semiconductor devices using damascene or dual damascene processing techniques. In damascene or dual damascene processing, trench openings, via openings or two-tiered (dual damascene) openings including trenches and vias, are formed in a dielectric layer or in a plurality of dielectric layers formed over a semiconductor substrate. The etching procedures used to form the openings produce straight sidewalls that are typically angled with respect to the dielectric upper surface. A conductive material is then blanket deposited over the dielectric, including filling the trench, via or dual damascene openings A polishing operation such as chemical mechanical polishing, CMP, is then used to planarize the upper surface and is designed to remove the conductive material from over the dielectric layer or layers, the conductive material remaining within the openings. In this manner, an interconnect structure is formed within each opening and this interconnect structure is bounded laterally and subjacently by the dielectric layer or layers.

The interconnect structure has a planar top surface coplanar with the polished planar top surface of the dielectric layer or layers in which it is formed. The interconnect structure may extend laterally to connect remote devices that are laterally separated and/or it may be contacted subjacently to a semiconductor device or devices disposed beneath the interconnect structure. For example, a tungsten or other contact plug may be formed extending downward from a trench bottom before the trench is filled with the conductive material. Common conductive materials used to form such interconnect structures include copper, aluminum, and alloys thereof.

A shortcoming associated with conventional processing is that the interconnect structures formed in the openings after polishing have straight sidewalls that undesirably form sharp edges at the upper surface of the interconnect structures especially for trapezoidal cross sections in which the top of the interconnect structure includes a width greater than the bottom of the interconnect structure, i.e., the upper edges of the interconnect structures are defined by acute angles. The sharp upper edges create leakage currents when current is run through the structure. Such leakage can degrade device performance or result in a non-functional device. It would therefore be desirable to eliminate this shortcoming.

In today's rapidly advancing semiconductor manufacturing industry, it is also a challenge to increase device integration levels by reducing feature sizes and enabling features, such as interconnect structures, to be formed closer and closer together. For example, semiconductor device design includes design rules for parameters such as minimum spacing between adjacent components. One challenge in semiconductor manufacturing is to reduce the minimum spacing design rules, i.e., the minimum spacing that designers must allow between adjacent features in view of process capabilities, to insure device reliability. Alternatively, it would be desirable to increase the density of device features for a given set of design rules. It would therefore be further desirable to produce a method for increasing the level of device integration as well as reducing device leakage in conductive interconnect structures.

### SUMMARY OF THE INVENTION

To address these and other needs and in view of its purposes, the invention provides, in one aspect, a semiconductor interconnect structure. The semiconductor interconnect structure includes a dielectric layer with an upper surface, a trench opening extending downwardly from the upper surface and into the dielectric layer, and an interconnect structure comprising a conductor material filling the trench opening and extending above the upper surface. The interconnect structure has a top surface with a generally planar central portion being generally parallel the upper surface, and downwardly rounded edges.

According to another aspect, a method for forming an interconnect structure within a semiconductor device is provided. The method includes providing a semiconductor structure including conductive structures filling openings formed in a dielectric layer and having a planar upper surface including an upper planar dielectric surface and top planar conductive surfaces, each conductive structure having opposed upper edges formed of an intersection of the planar conductive surface and the generally straight sidewalls, and performing a processing operation that both downwardly recedes the upper planar dielectric surface and inwardly recedes and rounds the upper edges.

According to another aspect, a method for increasing minimum spacing between adjacent formed interconnect structures is provided. The method includes forming interconnect structures in adjacent openings formed in a dielectric layer, each of the interconnect structures having a top surface coplanar with a planar upper surface of said dielectric layer. Adjacent interconnect structures have a first minimum spacing therebetween. The method further provides for performing an operation that both etches a depth of the dielectric layer and laterally recedes each of opposed upper edges of the interconnect structures to provide a second minimum spacing between the interconnect structures, the second minimum spacing being greater than the first minimum spacing.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1-2 are cross-sectional views illustrating a sequence of process operations for forming inventive interconnect structures. FIG. 1 is a structure as in the PRIOR ART.

FIGS. 3A and 3B are cross-sectional views showing two successive process steps that illustrate another advantageous aspect of the invention.

### DETAILED DESCRIPTION

The invention provides an interconnect structure formed using damascene or dual damascene techniques but which extends above the upper surface of the dielectric material in which it is formed and includes rounded upper edges. Also provided are methods for forming the structure.

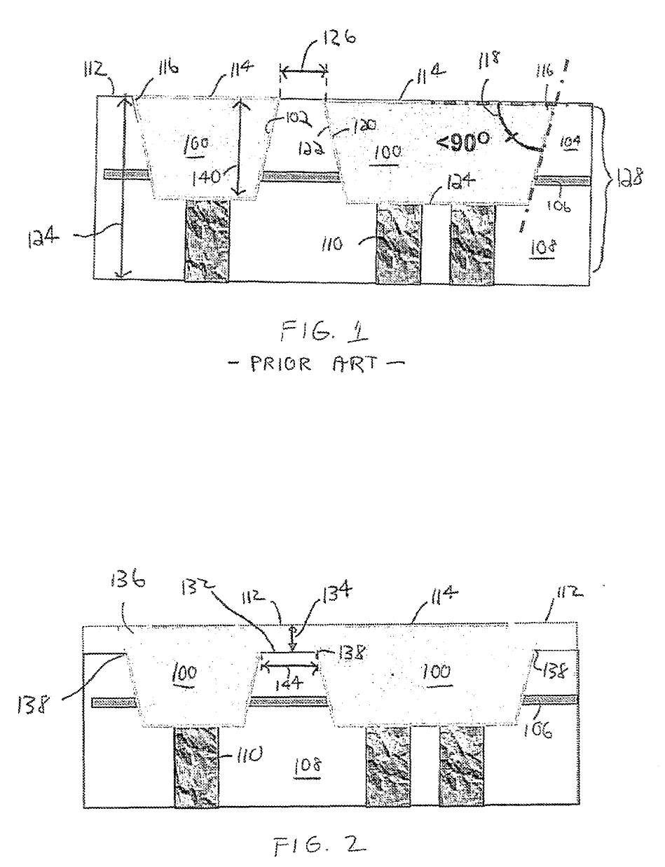

FIG. 1 is a cross-sectional view of two exemplary adjacent interconnect structures. Interconnect structures 100 are formed in dielectric 128. Dielectric 128 may consist of one or several dielectric layers. In the illustrated embodiment, there are three dielectric layers. Dielectric layer 108 may be any of various suitable dielectric materials such as oxides, nitrides, oxynitrides, spin-on glass materials, BPSG (borophosphosilicate glass), FSG (fluorosilicate glass) or various suitable low-k dielectric materials. Dielectric layer 104 may be FSG in one exemplary embodiment but other suitable intermetal dielectrics such as listed above, may be used in other exemplary embodiments. Dielectric layer 106 may be silicon nitride according to an exemplary embodiment. Illustrated dielectric material 128 is intended to be exemplary only and in other exemplary embodiments, more or fewer dielectric layers may be present and they may be formed in various materials. Aggregate thickness 124 of dielectric 128 may range from 1000 to 100,000 angstroms in various exemplary embodiments.

Interconnect structures 100 are formed of conductive materials that fill openings 102 formed in dielectric 128. Openings 102 may be trench or other openings formed using conventional methods and, as formed, include straight sidewalls 122. The conductive materials used to form interconnect structures 100 may be copper, aluminum, alloys thereof, or other suitable conductive materials. Although not illustrated, the interconnect structures 100 may also include one or more barrier layers surrounding the bulk conductive material. As formed within openings 102, interconnect structures 100 include sidewalls 120 that are conterminous with trench sidewalls 122 of openings 102. Interconnect structures 100 includes bottoms 124 and plugs 110 may subjacently extend from bottom 124 to couple interconnect structures 100 to underlying semiconductor devices (not shown). Plugs 110 may advantageously be formed of tungsten, but other suitable conductive materials may be used in other exemplary embodiments. Interconnect structures 100 may extend in and out of the plane of the drawing page to connect laterally separated devices to each other. In the illustrated embodiment, interconnect structures 100 are generally trapezoidal in shape but in other exemplary embodiments, interconnect structures 100 may be square or rectangular or may include bottom 124 being non-planar. In the illustrated embodiment, the top portions of interconnect structures 100 have a greater width than bottom portions 124. The planarized upper surface of the illustrated structure include upper dielectric surfaces 112 which are coplanar with top conductive surfaces 114. Interconnect structures 100 include a height 140 that may vary from 500 to 50,000 angstroms but other heights i.e., the depth of trench openings 102 after polishing, may be used in other exemplary embodiments depending upon various processing and device considerations. Conventional damascene and dual damascene processing techniques are known and may be used. Many of the techniques utilize an upper etch stop dielectric layer that may remain after polishing but is not shown in FIG. 1. Upper corners 116 of interconnect structures 100 include an acute angle 118 formed by the intersection of top conductive surfaces 114 and straight sidewalls 120 in the illustrated embodiment but the sharp edges may include orthogonal surfaces in other exemplary embodiments. Minimum spacing 126 between adjacent interconnect structures 100 is determined by design rules and process capabilities. The numerical value for minimum spacing 126 may vary in various exemplary embodiments and may be about 100 nm in one exemplary embodiment.

A processing operation or operations is then performed on the structure shown in FIG. 1 to produce the structure shown in FIG. 2 in which interconnect structures 100 include rounded upper edges 136 and in which top conductive surfaces 114 extends above receded dielectric surface 132. The processing operation or operations may include a wet etching step operation, a dry etching operation or a combination of wet and dry etching operations. In one exemplary embodiment the dry etching may be ion bombardment and in another exemplary embodiment the dry etching may be ion milling. In another exemplary embodiment, reactive ion etching may be used. The processing operation or operations may include one or more dry etching processes used to selectively etch dielectric layer 104 (e.g. reactive ion etching, RIE) but including etch conditions controlled to provide sufficient ion milling and/or ion bombardment characteristics to recede original upper edges 116. For example, the process gas or gasses, pressure and/or the power applied to a dry etching operation are selected to produce ion bombardment that produces a thickness loss in dielectric layer 104 and exposes the corners of interconnect structures 100 and then etches and smooths the upper edges to produce rounded edges 136. In other embodiments chemical species and other conditions (e.g., temperature) of a wet etching operation carried out in conjunction with a dry etching operation, may be controlled to bring about such effects. In other words, the etch process is not perfectly selective. The processing operation or operations produce the structure shown in FIG. 2 in which receded dielectric surface 132 is receded by distance 134 with respect to original upper dielectric surface 112 (shown by dashed lines). Distance 134 may vary from 100 to 1500 angstroms in various exemplary embodiments but other distances of recession may be used in other exemplary embodiments. It can be seen that portions of interconnect structures 100 that are above receded upper dielectric surface 132, are rounded. Rounded edges 136 are the result of the processing operation or operations that inwardly recede and round original upper edges 116 (FIG. 1). Original upper edges 116 may be receded by as much as 1000 angstroms as rounded edges 136 are formed.

Interconnect structures 100 shown in FIG. 2 having rounded edges are resistant to leakage. Minimum spacing 144 between adjacent interconnect structures 100 is formed at the intersection of rounded edges 136 and straight sidewalls 120, i.e., along receded dielectric surface 132. It is thereby demonstrated that, for adjacent interconnect structures 100 formed in a dielectric material and separated by a fixed distance, the processing techniques of the invention increase the minimum spacing between the adjacent interconnect structures 100. In this manner, for a given design rule requiring a certain minimum distance between final structures such as, for example, 10 microns (i.e. the final formed devices must be spaced apart by 10 microns or greater) adjacent interconnect structures 100 may be originally formed in closer proximity than previously possible according to one aspect of the invention.

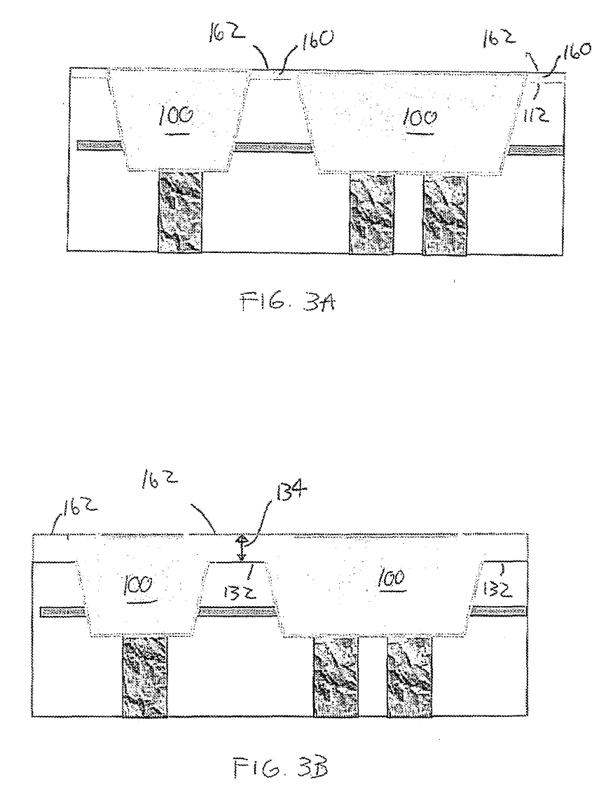

FIGS. 3A and 38 illustrate how the method of the invention provides the advantage of overcoming incomplete polishing operations. FIG. 3A shows interconnect structures 100 similar to those illustrated in the previous figures but instead of top conductive surfaces 114 being coplanar with upper dielectric surface 112, there is a residual conductive film 160 over upper dielectric surface 112 and in the illustrated embodiment, top conductive surfaces 114 of interconnect structures 100 are coplanar with original upper surface 162 of residual conductive film 160. As the sizes of semiconductor substrates, i.e. wafers used in semiconductor processing increases, so, too, does the likelihood that a variation in the height of the dielectric surface throughout the substrate will result in incomplete polishing in sections of the substrate, leaving artifacts such as residual conductive film 160. When the process operation or operations of the invention is performed upon the structure shown in FIG. 3A, the structure shown in FIG. 3B results. The illustration of FIG. 3B is essentially the same as the illustration of FIG. 2 with the distinction being that distance 134 represents the distance between original upper surface 162 and receded dielectric surface 132.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid in understanding the principles of the invention and the concepts contributed to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. A semiconductor interconnect structure comprising:
a dielectric layer with an upper surface;
a trench opening extending downwardly from said upper surface and into said dielectric layer;
an interconnect structure comprising a conductor material filling said trench opening and extending above said upper surface, said interconnect structure having a top surface, said top surface including a generally planar central portion being generally parallel said upper surface, and downwardly rounded upper edges.

2. The semiconductor interconnect structure as in claim 1. wherein said downwardly rounded upper edges are rounded down to said upper surface.

3. The semiconductor interconnect structure as in claim 1, wherein said interconnect structure includes opposed generally straight sides below said upper surface and intersections between said rounded edges and said generally straight sides form lateral extremities of said interconnect structure.

4. The semiconductor interconnect structure as in claim 3, wherein said generally planar central portion of said top surface forms an acute angle with said straight sides.

5. The semiconductor interconnect structure as in claim 1, wherein said upper surface and said generally planar central portion of said top surface are separated by a distance of about 100 to 10,000 angstroms.

6. The semiconductor interconnect structure as in claim 1, wherein said interconnect structure is subjacently coupled to at least an underlying semiconductor device by way of a conductive plug.

7. The semiconductor interconnect structure as in claim 1, wherein said dielectric layer is a composite of a plurality of dielectric films.

8. A method for forming an interconnect structure within a semiconductor device comprising:
providing a semiconductor structure including conductive structures filling openings formed in a dielectric layer and having a planar upper surface including an upper planar dielectric surface and top planar conductive surfaces, each conductive structure having opposed upper edges formed of an intersection of said planar conductive surface and said generally straight sidewalls; and
performing a processing operation that both downwardly recedes said upper planar dielectric surface and inwardly recedes and rounds said upper edges.

9. The method as in claim 8, wherein said generally straight sidewalls are conterminous with sidewalls of said opening and said top planar conductive surfaces each form an acute angle with said generally straight sidewalls prior to said performing.

10. The method as in claim 8, wherein said performing a processing operation causes said upper planar dielectric surface to recede by about 100 to 10,000 angstroms and said opposed upper edges to each be receded by about 1000 angstroms. 11. The method as in claim 8, wherein said performing a processing operation includes at least one of ion milling and ion bombardment.

12. The method as in claim 8, wherein said processing operation is a two step operation including a wet processing portion and a dry processing portion.

13. The method as in claim 8, wherein said providing comprises:
creating said openings within said dielectric layer, said dielectric layer comprising a plurality of dielectric films;
depositing conductive material at least filling said openings and over said dielectric layer; and
polishing to form said planar upper surface.

14. A method for increasing minimum spacing between adjacent formed interconnect structures, said method comprising:
forming interconnect structures in adjacent openings formed in a dielectric layer. each of said interconnect structures having a top surface coplanar with a planar upper surface of said dielectric layer, said adjacent interconnect structures having a first minimum spacing therebetween;
performing an operation that both etches a depth of said dielectric layer and laterally recedes each of opposed upper edges of said interconnect structures to provide a second minimum spacing between said interconnect structures, said second minimum spacing being greater than said first minimum spacing;
said interconnect structures formed of conductive materials.

15. The method as in claim 14, wherein said performing an operation includes forming a receded upper surface of said dielectric layer, and edge portions of said interconnect structure that are above said receded upper surface are rounded and receded laterally.

16. The method as in claim 14, wherein, prior to said performing an operation, each of said opposed upper edges forms an acute angle, said first minimum spacing being a distance between said opposed upper edges along said top surface and wherein said second minimum spacing is at a location below said first minimum spacing.

17. The method as in claim 14, wherein said performing an operation does not significantly recede respective central portions of said top surfaces.

18. The method as in claim 14, wherein said performing an operation comprises a reactive ion etching process that etches said dielectric layer and also laterally recedes and rounds said upper edges.

19. The method as in claim 14, wherein said operation includes at least one of ion milling and ion bombardment.

20. The method as in claim 14, wherein said performing an operation comprises a two-step operation including a wet processing operation and a dry processing operation.
